(19) United States
(12) Patent Application Publication
(10) Pub. No.: US 2026/0008134 A1
(43) Pub. Date: Jan. 8, 2026

(54) METHOD OF MANUFACTURING SEMICONDUCTOR ELEMENT AND SEMICONDUCTOR ELEMENT

(71) Applicant: NICHIA CORPORATION, Anan-shi (JP)

(72) Inventors: Takashi ABE, Anan-shi (JP); Eiji SHIRAKAWA, Anan-shi (JP); Yoji OGAWA, Tokushima-shi (JP)

(73) Assignee: NICHIA CORPORATION, Anan-shi (JP)

(21) Appl. No.: 19/255,498

(22) Filed: Jun. 30, 2025

(30) Foreign Application Priority Data
Jul. 5, 2024 (JP) 2024-108950

(51) Int. Cl. B23K 26/53; B23K 26/082; B23K 26/38; B23K 101/40; H01L 21/304; H01L 21/78

(52) U.S. Cl. CPC B23K 26/53; B23K 26/082; B23K 26/38; H01L 21/3043; H01L 21/78; B23K 2101/40

(57) ABSTRACT

A method of manufacturing a semiconductor element includes: a first process that includes forming a first modified portion in the substrate, and forming a second modified portion at a position next to the first modified portion in a first direction, and a process of forming a plurality of third modified portions arranged in a thickness direction of the substrate at positions that are closer to the first face of the substrate than is the first modified portion and overlapping the first modified portion in a plan view. No modified portions are formed at positions that are next to the third modified portions in the first direction to overlap the second modified portions in a plan view. The number of the first modified portions arranged in the thickness direction is equal to or less than the number of the third modified portions arranged in the thickness direction.

### CROSS-REFERENCE TO RELATED APPLICATION

This application claims priority to Japanese Patent Application No. 2024-108950, filed on Jul. 5, 2024, the disclosure of which is hereby incorporated by reference in its entirety.

### TECHNICAL FIELD

The present disclosure relates to a method of manufacturing a semiconductor element and a semiconductor element.

### BACKGROUND

Semiconductor elements are generally obtained by cutting a wafer in which semiconductor layers are formed on a substrate. As a method of cutting a wafer, there is known a method that forms a modified region in a substrate by focusing laser light within the substrate, followed by splitting the wafer using a crack extending from the modified region as a starting point. For example, Japanese Patent Publication No. 2013-48207 discloses a laser cutting method that forms two parallel columns of modified regions in a cutting street by irradiating laser light along the first straight line and a second straight line.

### SUMMARY

An object of the present disclosure is to provide a method of manufacturing a semiconductor element and a semiconductor element in which substrate chipping is less likely to occur.

A method of manufacturing a semiconductor element according to one mode of the present disclosure comprises: a process of providing a substrate having a first face and a second face; a first process including a process of forming a first modified portion by irradiating laser light within the substrate from the first face side of the substrate and, subsequent to the process of forming a first modified portion, a process of forming a second modified portion at a position next to the first modified portion in the first direction which is parallel to the first face by irradiating laser light from the first face side at a position apart from the first modified portion in the first direction; subsequent to the first process, a process of forming a plurality of third modified portions arranged in the thickness direction of the substrate at positions that overlap the first modified portion in a plan view and are closer to the first face than the first modified portion is by irradiating laser light from the first face side; and subsequent to the process of forming third modified portions, a process of splitting the substrate by pressuring the substrate from the second face side using a pressure member, wherein modified portions are not formed next to the third modified portions in the first direction to overlap the second modified portions in a plan view, and the number of the first modified portions arranged in the thickness direction is set to be equal to or less than the number of the third modified portions arranged in the thickness direction.

A semiconductor element according to one mode of the present disclosure comprises a substrate having a first face, a second face, a first lateral face connecting the first face and the second face, and a second lateral face positioned opposite the first lateral face in the first direction which is parallel to the first face and connecting the first face and the second face; and semiconductor layers disposed on the second face, wherein the first lateral face has a first region, a second region having a larger surface roughness than that of the first region, and a plurality of third regions positioned closer to the first face than the second region is, having a larger surface roughness than that of the first region, and arranged in the thickness direction of the substrate, the second lateral face has a fourth region and a plurality of fifth regions having a larger surface roughness than that of the fourth region and arranged in the thickness direction, the substrate has within the substrate a modified portion that is positioned only next to the second region in the first direction, the distance between the first lateral face and the modified portion in the first direction is smaller than the distance between the second lateral face and the modified portion in the first direction, and the number of the second regions arranged in the thickness direction is equal to or less than the number of the third regions arranged in the thickness direction.

According to the present disclosure, a method of manufacturing a semiconductor element and a semiconductor element capable of reducing substrate chipping can be provided.

### BRIEF DESCRIPTION OF THE DRAWINGS

FIG. 1 is a schematic plan view explaining a process in a method of manufacturing a semiconductor element according to one embodiment.

FIG. 2 is a schematic cross-sectional view explaining a process in the method of manufacturing a semiconductor element according to the embodiment.

FIG. 3 is a schematic plan view explaining a process in the method of manufacturing a semiconductor element according to the embodiment.

FIG. 4 is a schematic plan view explaining a process in the method of manufacturing a semiconductor element according to the embodiment.

FIG. 5 is a schematic plan view explaining a process in the method of manufacturing a semiconductor element according to the embodiment.

FIG. 6 is a schematic cross-sectional view explaining a process in the method of manufacturing a semiconductor element according to the embodiment.

FIG. 7 is a schematic cross-sectional view explaining a process in the method of manufacturing a semiconductor element according to the embodiment.

FIG. 8A is a schematic plan view explaining a process in the method of manufacturing a semiconductor element according to the embodiment.

FIG. 8B is a schematic plan view explaining a process in the method of manufacturing a semiconductor element according to the embodiment.

FIG. 9 is a schematic cross-sectional view explaining a process in the method of manufacturing a semiconductor element according to the embodiment.

FIG. 10 is a schematic cross-sectional view explaining a process in the method of manufacturing a semiconductor element according to the embodiment.

FIG. 11A is a schematic cross-sectional view explaining a process in the method of manufacturing a semiconductor element according to the embodiment.

FIG. 11B is a schematic cross-sectional view explaining a process in the method of manufacturing a semiconductor element according to the embodiment.

FIG. 11C is a schematic cross-sectional view explaining a process in the method of manufacturing a semiconductor element according to the embodiment.

FIG. 12 is a schematic cross-sectional view of a semiconductor element according to an embodiment.

### DETAILED DESCRIPTION

Methods of manufacturing a semiconductor element and semiconductor elements according to certain embodiments of the present disclosure will be explained below with reference to the accompanying drawings. Described below are examples of methods of manufacturing a semiconductor element and semiconductor elements provided to give shape to the technical ideas of the embodiments, but the invention is not limited to the embodiments described below. The materials for, and dimensions, shapes, and relative positions of the constituent elements described in the embodiments are not intended to limit the scope of the present invention unless specifically noted, and are merely provided as explanatory examples. The sizes of and positional relationships between the members in each drawing might be exaggerated for clarity of explanation. In the description below, the same designations or reference numerals denote the same or similar members, for which detailed explanation will be omitted as appropriate. As a cross-sectional view, an end view only showing a cut section might be used.

In the explanation below, terms indicating specific directions or positions (for example, “above,” “upper,” or “under,” “lower” or other terms related thereto) may occasionally be used. These terms, however, are merely used to clarify the relative directions or positions in a referenced drawing. As long as the relationship between relative directions or positions indicated with the terms such as “upper,” “above,” “lower,” “under,” or the like is the same as those in a referenced drawing, the layout of the elements in other drawings or actual products outside of the present disclosure does not have to be the same as those shown in the referenced drawing. The positional relationship expressed as “on” includes, assuming that there are two members, cases in which the two members are in contact with one another and cases in which one of the two members is positioned above the other without being in contact. Furthermore, in the present specification, the width, the distance, the thickness, or the length of a member in a specific direction represents the maximum value of the width, the distance, the thickness, or the length of the member in the specific direction.

### [Method of Manufacturing Semiconductor Element]

A method of manufacturing a semiconductor element according to one embodiment includes a process of providing a wafer W, a process of forming modified portions within the substrate 10, and a process of splitting the substrate 10.

### <Process of Providing Wafer>

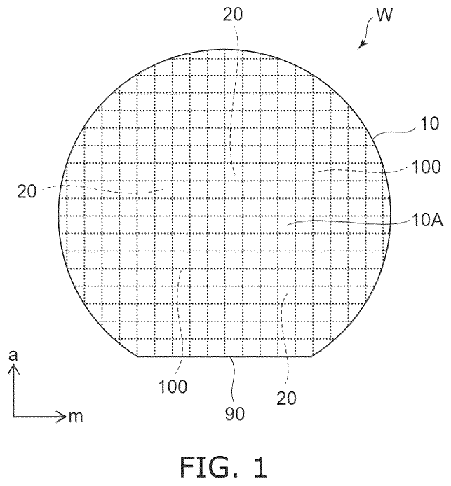

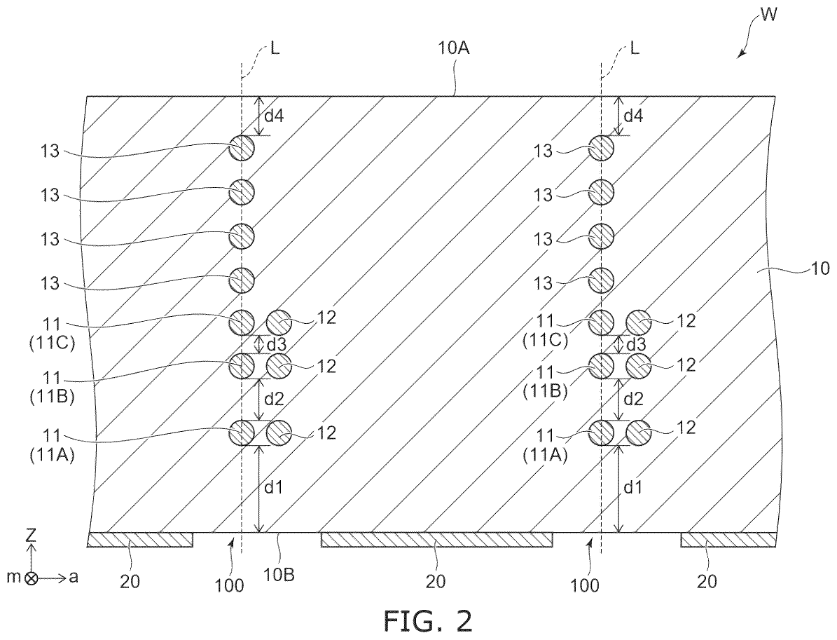

FIG. 1 is a plan view of a wafer W. FIG. 2 is a schematic cross-sectional view showing a portion of a cross section of the wafer W.

The wafer W has a substrate 10. The substrate 10 is, for example, a sapphire substrate. In FIG. 1, the a-axis direction and the m-axis direction of the sapphire substrate are shown. The orientation flat 90 of the sapphire substrate 10 is the face that is parallel to a-plane of the sapphire substrate.

The cross sections shown in the drawings in the present disclosure are those that are orthogonal to the a-axis direction or the m-axis direction of the sapphire substrate. FIG. 2 shows a cross section that is orthogonal to the m-axis direction. The thickness direction Z of the substrate 10 (hereinbelow simply referred to as the thickness direction Z on occasion) is orthogonal to the a-axis direction and the m-axis direction. The substrate 10 has a first face 10A and a second face 10B that is positioned opposite the first face 10A in the thickness direction Z of the substrate 10. The second face 10B is, for example, c-plane of the sapphire substrate. The second face 10B may be oblique to c-plane of the sapphire substrate to the extent of allowing for the formation of semiconductor layers 20 with good crystallinity.

The semiconductor layers 20 are disposed on the second face 10B of the substrate 10. In this embodiment, the semiconductor element is a light emitting element, and the semiconductor layers include an active layer that emits light. The semiconductor layers 20 include, for example, nitride semiconductors represented by InₓAl_{y}Ga_{1-x-y}N (0≤x≤1, 0≤y≤1, x+y≤1). The peak wavelength of the light emitted by the active layer of the semiconductor layers 20 is, for example, 200 nm to 600 nm. The active layer of the semiconductor layers 20 emits ultraviolet light, for example.

A conductive member electrically connected to the semiconductor layers 20, a protective film covering the semiconductor layers 20, and the like may be further disposed on the second face 10B side of the substrate 10.

In the process of forming modified portions described below, laser light is irradiated on the substrate 10 along cutting regions 100 of the substrate 10. In this embodiment, multiple cutting regions 100 extend along the a-axis direction and the m-axis direction.

The cutting regions 100, located between semiconductor elements for splitting the substrate 10 thereby dividing the elements into individual pieces, are set to have a width such that the splitting of the substrate 10 would not adversely affect the semiconductor elements. The semiconductor layers 20 may be, or do not have to be, disposed in the cutting regions 100 of the second face 10B. In this embodiment, no semiconductor layers 20 are disposed in the cutting regions 100 of the second face 10B. In a plan view, the width of a cutting region 100 in the direction orthogonal to the extending direction of the cutting region 100 is, for example, 10 μm to 50 μm. FIG. 2 shows a cross section that includes two cutting regions 100 that extend in the m-axis direction.

### <Process of Forming Modified Portions>

First modified portions 11, second modified portions 12, and third modified portions 13 are formed in the substrate 10 by irradiating laser light within the substrate 10 from the first face 10A side of the substrate 10. Laser light rays are focused at a position within the substrate 10 at a predetermined distance from the first face 10A at which the laser light energy is concentrated. First modified portions 11, second modified portions, and third modified portions 13 are formed in the regions within the substrate 10 in which the laser light is focused. The first modified portions 11, the second modified portions 12, and the third modified portions 13 differ from the surrounding non-modified region in terms of at least one of density, refractive index, and mechanical strength.

A crack occurs from each of the first modified portions 11, the second modified portions 12, and the third modified portions 13. At least a crack extending towards the first face 10A occurs from each of the first modified portions 11, the second modified portions 12, and the third modified portions 13 in the substrate 10.

Laser light scanning is conducted along each of the cutting regions 100. Laser light scanning is performed along the cutting regions 100 extending in one of the a-axis direction and the m-axis direction to form first modified portions 11, second modified portions 12, and third modified portions 13. This is followed by laser light scanning along the cutting regions 100 extending in the other direction to form first modified portions 11, second modified portions 12, and third modified portions 13. For example, after forming first modified portions 11, second modified portions 12, and third modified portions 13 by performing laser light scanning along the cutting regions 100 extending in the a-axis direction, first modified portions 11, second modified portions 12, and third modified portions 13 can be formed by performing laser light scanning along the cutting regions 100 extending in the m-axis direction.

The laser light is emitted in the form of pulses, for example. The pulse width of the laser light is, for example, 100 femtoseconds to 1000 picoseconds. As a laser light source, for example, an Nd:YAG laser, titanium sapphire laser, Nd:YVO4 laser, Nd:YLF laser, or the like can be used. The wavelength of the laser light is the wavelength of the light that transmits through the substrate 10. The laser light has a peak wavelength in a range of 500 nm to 1200 nm.

The process of forming modified portions has a first process and a second process.

### (First Process)

A first process has a process of forming a first modified portion 11 and a process of forming a second modified portion 12.

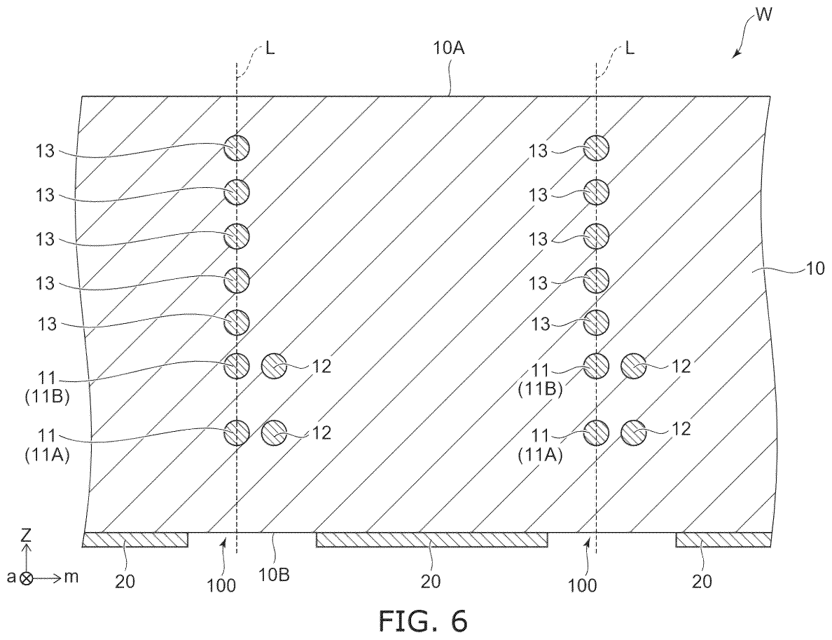

The direction parallel to the first face 10A in which a first modified portion 11 and a second modified portion 12 are arranged side by side is designated as the first direction. In this embodiment, the first direction is parallel to the a-axis direction or the m-axis direction. In the cross sections shown in FIGS. 2, 9, and 10, the first direction is parallel to the a-axis direction. In other words, when conducting laser light scanning in the m-axis direction, the first direction is parallel to the a-axis direction. In the cross section shown in FIG. 6, the first direction is parallel to the m-axis direction. In other words, when performing laser light scanning in the a-axis direction, the first direction is parallel to the m-axis direction. Furthermore, the direction parallel to the first face 10A and orthogonal to the first direction is designated as the second direction. In the cross sections shown in FIGS. 2, 9, and 10, the second direction is parallel to the m-axis direction. In other words, when conducting laser light scanning in the m-axis direction, the second direction is parallel to the m-axis direction. In the cross section shown in FIG. 6, the second direction is parallel to the a-axis direction. In other words, when conducting laser light scanning in the a-axis direction, the second direction is parallel to the a-axis direction.

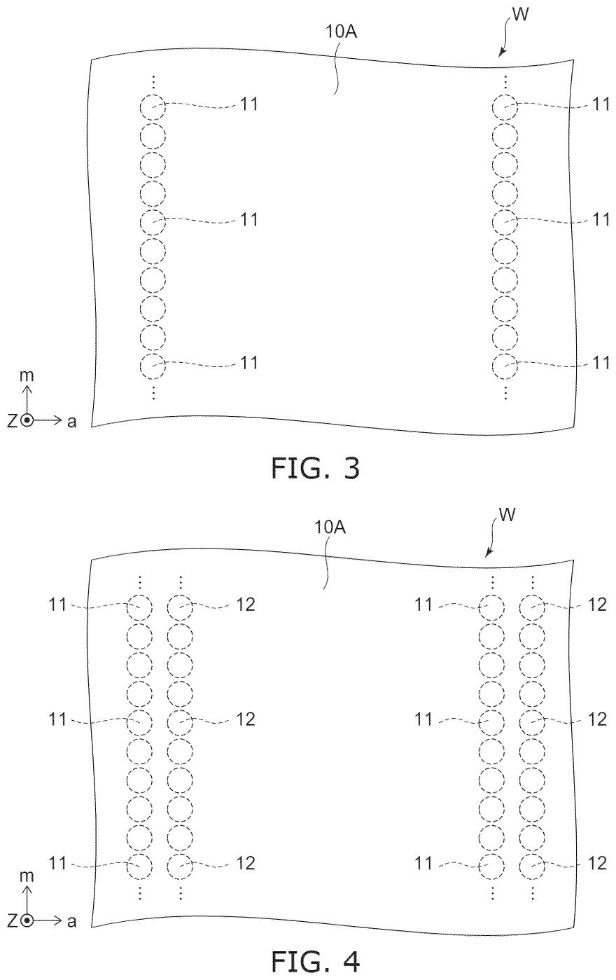

A first modified portion 11 is formed within the substrate 10 by irradiating laser light within the substrate 10 from the first face 10A side of the substrate 10. In the process of forming a first modified portion 11, laser light is irradiated within the substrate 10 while conducting laser light scanning along the m-axis direction. This forms multiple first modified portions 11 along the m-axis direction as shown in FIG. 3. The multiple first modified portions 11 are formed apart from one another along the m-axis direction, for example. The first modified portions 11 may be formed such that adjacent first modified portions 11 in the m-axis direction are in contact with or overlapping one another in part.

The pulsed laser energy for forming the first modified portions 11 is preferably 0.1 μJ to 20.0 μJ, for example, more preferably 1.0 μJ to 15.0 μJ, even more preferably 2.0 μJ to 10.0 μJ.

Subsequent to the process of forming a first modified portion 11, a second modified portion 12 is formed to be adjacent in the first direction (in the a-axis direction in FIG. 2) to a first modified portion 11 by irradiating laser light from the first face 10A side at a position apart from the first modified portion 11 in the first direction. In the process of forming a second modified portion 12, laser light is irradiated within the substrate 10 while conducting laser light scanning along the m-axis direction. This forms multiple second modified portions 12 along the m-axis direction as shown in FIG. 4. The multiple second modified portions 12 are formed apart from one another along the m-axis direction. The second modified portions 12 may be formed such that adjacent second modified portions 12 in the m-axis direction are in contact with or overlapping one another in part. In a plan view, a column of second modified portions 12 arranged in the m-axis direction are positioned to be adjacent in the first direction (in the a-axis direction in FIG. 4) to the first modified portions 11 arranged in the m-axis direction.

As shown in FIG. 2, the first modified portions 11 and the second modified portions 12 are next to one another in the first direction (the a-axis direction) within the width of a cutting region 100. The first modified portions 11 and the second modified portions 12 do not overlap the semiconductor layers 20 in a plan view.

Forming the second modified portions 12 next to the first modified portions can facilitate the extension of cracks originating from the first modified portions 11. A crack occurs from a modified portion as the strain occurring during the formation of the modified portion is released. When a modified portion is newly formed in the vicinity of the region in which a crack has already occurred from a modified portion, the force generated when the strain is released presumably acts on not only the newly occurring crack from the newly formed modified portion, but also the crack that has already occurred. In other words, the forces generated as the strain that occurred during the formation of second modified portions 12 are released presumably act on the cracks extending from the first modified portions 11 which have already been formed, thereby facilitating the extension of the cracks occurring from the first modified portions 11. This can facilitate the splitting of even a thick substrate 10 in the process of splitting the substrate 10 described later. The thickness of the substrate 10 is, for example, 100 μm to 1500 μm, preferably 150 μm to 1200 μm, even more preferably 300 μm to 1000 μm.

The distance in the first direction between a first modified portion 11 and a second modified portion 12 positioned side by side in the first direction is preferably 2 μm to 10 μm, for example. This makes it easier for the force generated as the strain occurring during the formation of the second modified portion 12 is released to act on the cracks extending from the first modified portion 11 that has already been formed. Here, the distance in the first direction between a first modified portion 11 and a second modified portion means the shortest distance in the first direction between the outer edge of the first modified portion 11 and the outer edge of the second modified portion 12.

The pulsed laser energy for forming the second modified portions 12 is preferably 0.1 μJ to 20.0 μJ, for example, more preferably 1.0 μJ to 15.0 μJ, even more preferably 2.0 μJ to 10.0 μJ.

The first process that includes the process of forming a first modified portion 11 and the process of forming a second modified portion 12 next to the first modified portion 11 may be conducted only once, or multiple times. In this embodiment, the first process is conducted multiple times. In other words, the first process is conducted multiple times to arrange multiple first modified portions 11 in the thickness direction Z of the substrate 10 so as to overlap one another in a plan view and multiple second modified portions 12 arranged in the thickness direction Z of the substrate 10 so as to overlap one another in the plan view.

In the example shown in FIG. 2, the first modified portions 11 include a first portion 11A, a second portion 11B, and a third portion 11C. The first portion 11A, the second portion 11B, and the third portion 11C are arranged apart from one another in the thickness direction Z. Among the first to third portions 11A to 11C, the first portion 11A is positioned closest to the second face 10B. The second portion 11B is positioned closer to the first face 10A than the first portion 11A is, and the third portion 11C is positioned closer to the first face 10A than the second portion 11B is.

Forming multiple first modified portions 11 arranged in the thickness direction Z of the substrate 10 allows the cracks originating from the first modified portions 11 to be easily connected in the thickness direction Z, thereby facilitating the splitting of even a thick substrate 10.

The first process that is conducted multiple times includes a process of forming a first modified portion 11 and a process of forming a second modified portion 12 next to the first modified portion 11 in the first direction each time. In the example shown in FIG. 2, a first portion 11A among the first modified portions 11 is formed first. Subsequent to forming the first portion 11A, a second modified portion 12 is formed next to the first portion 11A in the first direction. Subsequent to forming the second modified portion 12 next to the first portion 11A, a second portion 11B among the first modified portions 11 is formed at a position that overlaps the first portion 11A in a plan view. Subsequent to forming the second portion 11B, a second modified portion 12 is formed next to the second portion 11B in the first direction. The second modified portion 12 to be formed next to the second portion 11B in the first direction can be formed at a position that overlaps the second modified portion formed next to the first portion 11A in the plan view. Subsequent to forming the second modified portion 12 next to the second portion 11B, a third portion 11C among the first modified portions 11 is formed at a position that overlaps the second portion 11B in the plan view. Subsequent to forming the third portion 11C, a second modified portion 12 is formed next to the third portion 11C in the first direction. The second modified portion 12 formed next to the third portion 11C in the first direction can be formed at a position that overlaps the second modified portion 12 positioned next to the second portion 11B. For example, the second modified portions 12 overlap one another in the plan view. For example, the second modified portions 12 are arranged apart from one another in the thickness direction Z.

The numbers of the first modified portions 11 and the second modified portions 12 are not limited to three, and can be four or more, or two.

### (Second Process)

Subsequent to the first process for forming first modified portions 11 and second modified portions 12, third modified portions 13 are formed to be arranged in the thickness direction Z of the substrate 10 at positions that are closer to the first face 10A than the first modified portions 11 are and overlapping the first modified portions 11 in a plan view by irradiating laser light from the first face 10A side. The third modified portions 13 are arranged apart from one another in the thickness direction Z.

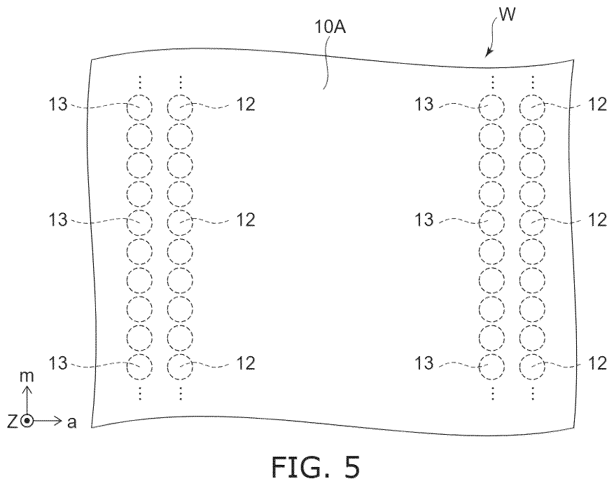

In the process of forming third modified portions 13, laser light is irradiated within the substrate 10 while conducting laser light scanning along the m-axis direction. This forms multiple third modified portions 13 along the m-axis direction as shown in FIG. 5. The third modified portions 13 are formed apart from one another in the m-axis direction, for example. The third modified portions 13 may be formed such that adjacent third modified portions 13 in the m-axis direction are in contact with or overlapping one another in part.

The pulsed laser energy for forming the third modified portions 13 is preferably 0.1 μJ to 20.0 μJ, more preferably 1.0 μJ to 15.0 μJ, even more preferably 2.0 μJ to 10.0 μJ, for example.

In the example shown in FIG. 2, four third modified portions 13 are formed in the thickness direction Z of the substrate 10. The number of third modified portions 13 arranged in the thickness direction Z of the substrate 10 may be two, three, or five or more.

As a result of forming third modified portions 13, cracks occur from the third modified portions 13. A crack extending from a third modified portion 13 towards the second face 10B can be connected to the crack which has extended from a first modified portion 11 towards the first face 10A. This can facilitate the splitting of the substrate 10.

A crack extending from a third modified portion 13 towards the first face 10A reaches the first face 10A, or reaches a position that is close to the first face 10A.

Modified portions are not formed at positions that are next to the third modified portions in the first direction and overlapping the second modified portions 12 in a plan view. Within the width of a cutting region 100, no modified portions exist next to the third modified portions 13 in the first direction. This can make it unlikely for the occurrence of cracks that reach or come close to the first face 10A at positions in the first direction that are next to the cracks extending from the third modified portions 13 and reaching or coming close to the first face 10A. The cracks extending from the second modified portions 12 do not come closer to the first face 10A than the cracks extending from the third modified portions 13. This can therefore limit the cracks that reach or come close to the first face 10A within the width of a cutting region 100 to only those that extend from the third modified portions 13.

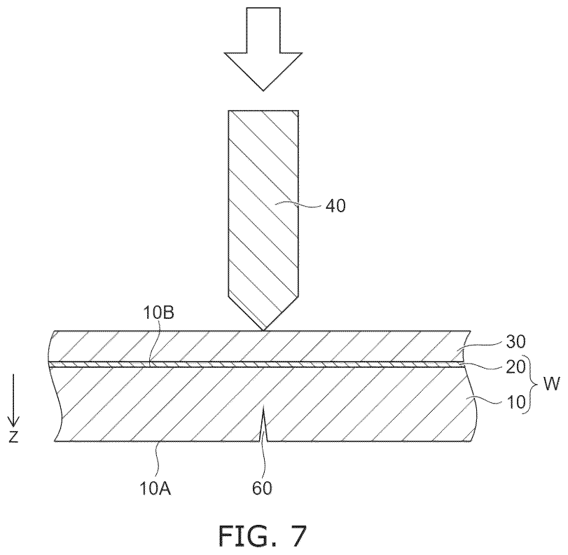

As described below with reference to FIG. 7, in the process of splitting the substrate 10, the substrate 10 begins splitting from the first face 10A side. Not forming modified portions at the locations that are next to the third modified portions 13 in the first direction can reduce the number of cracks that contribute to the initiation of the splitting of the first substrate 10 from the first face 10A side. For example, the cracks that contribute to the initiation of the splitting of the substrate 10 from the first face 10A side can be limited to those extending from the third modified portions 13. This can make the substrate 10 less susceptible to chipping when the substrate 10 begins to split from the first face 10A side, while facilitating the formation of cracks that extend towards the first face 10A. For example, in the case in which there are cracks respectively extending from two modified portions that are side by side in the first direction within the width of a cutting region 100 and reaching the first face 10A, the substrate 10 becomes prone to chipping when the substrate 10 begins to split from the first face 10A side.

In the process of forming modified portions, by conducting laser light scanning along multiple cutting regions 100 extending in the m-axis direction, first modified portions 11, second modified portions 12, and third modified portions 13 are formed along the cutting regions 100 extending in the m-axis direction as described above with reference to FIG. 2 to FIG. 5. In the process of forming modified portions, by further conducting laser light scanning along multiple cutting regions 100 extending in the a-axis direction, first modified portions 11, second modified portions 12, and third modified portions 13 are formed along the cutting regions 100 extending in the a-axis direction.

FIG. 6 is a cross section that includes first modified portions 11, second modified portions 12, and third modified portions 13 formed along multiple cutting regions 100 extending in the a-axis direction. The cross section in FIG. 6 includes two cutting regions 100 extending in the a-axis direction. For example, by conducting the first process twice, two first modified portions 11 arranged in the thickness direction Z and two second modified portions 12 arranged in the thickness direction Z next to the first modified portions 11 in the first direction (in this case, the m-axis direction) are formed. As described below, the number of times the first process is conducted along the a-axis direction can be set less than that of the first process conducted along the m-axis direction. Subsequent to the first process, for example, five third modified portions 13 arranged in the thickness direction Z are formed at the positions that overlap the first modified portions 11 in a plan view.

### <Process of Splitting Substrate>

Subsequent to the process of forming multiple third modified portions 13, the substrate 10 is split by pressuring the substrate 10 from the second face 10B side with a pressure member 40 as shown in FIG. 7.

For example, the face of the wafer W on which the semiconductor layers 20 are disposed is adhered to a sheet 30, and the substrate 10 is pressured with a pressure member 40 from the second face 10B side via the sheet 30. The pressure member 40 is, for example, a blade-shaped member extending along a cutting region 100. Upon receiving pressure from the pressure member 40 from the second face 10B side, the substrate 10 begins splitting using the cracks extending from the third modified regions 13 and reaching or coming close to the first face 10A as starting points. A groove 60 having a V-shaped cross section and opened in the first face 10A is formed along a cutting region 100, and the wafer W including the substrate 10 splits as the groove 60 reaches the second face 10B.

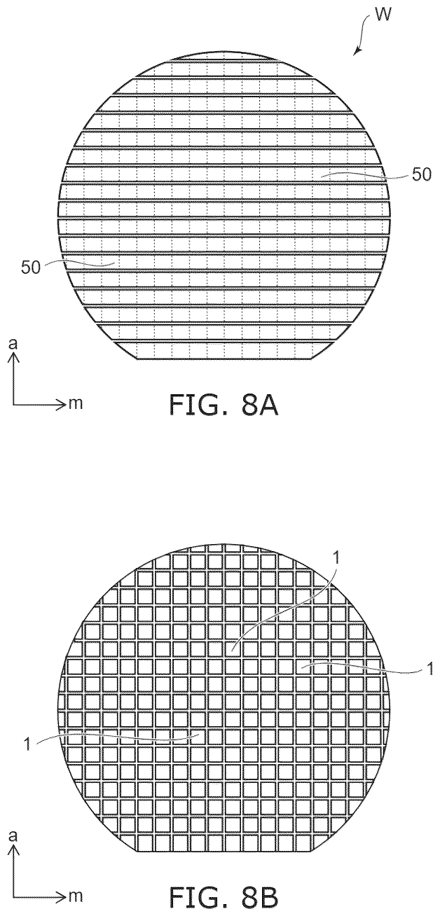

For example, the wafer W is split along multiple cutting regions 100 extending in the m-axis direction to thereby divide the wafer W into multiple bars 50 elongated in the m-axis direction as shown in FIG. 8A.

Subsequently, the bars 50 are split along multiple cutting regions 100 extending in the a-axis direction to thereby divide the wafer W into individual pieces of semiconductor elements 1 as shown in FIG. 8B. The wafer may be split along a-axis direction, before being split along the m-axis direction.

Subsequent to singulation, the first modified portions 11 and the third modified portions 13 are exposed at the lateral faces of individual semiconductor elements 1 as regions having a larger surface roughness than that of the region having no modified portions. Individual semiconductor elements 1 will be discussed below.

In a semiconductor element 1 according to this embodiment, which is a light emitting element, the light emitted by the active layer of the semiconductor layers 20 is extracted from the semiconductor element 1 through the first face 10A and the lateral faces of the substrate 10. The light is more readily extracted from the regions having modified portions exposed at the lateral faces of the substrate 10 than the regions of the lateral faces having no modified portions. This is thought to be because the modified portions exposed at the lateral faces of the substrate 10 have a larger surface roughness than those of the regions without modified portions in the lateral faces, and thus the light entering the substrate 10 is readily scattered at the modified portions exposed at the lateral faces of the substrate 10.

According to this embodiment, light is readily extracted from multiple regions of the third modified portions 13 arranged in the thickness direction Z at the lateral faces of the substrate 10, and one or more regions of the first modified portions 11 arranged in the thickness direction Z at the lateral faces 10 of the substrate 10.

Increasing the number of modified portions exposed at the lateral faces of the substrate 10 can increase the areas in the lateral faces of the substrate 10 through which light can be readily extracted. This can increase the light output of the semiconductor element 1.

In the cross section shown in FIG. 2, broken lines indicate target split lines L each passing through all of the multiple third modified portions 13 and all of the one or more first modified portions 11 arranged in the thickness direction Z. The target split lines L may be oblique to the first face 10A and the second face 10B as long as they go through all of the multiple third modified portions 13 and the one or more first modified portions 11 arranged in the thickness direction Z. Splitting the substrate 10 along the target split lines L exposes all of the multiple third modified portions 13 and all of the one or more first modified portions 11 at the lateral faces of the split substrate 10. If the substrate 10 is split at a position deviated from a target split line L, the number of modified portions exposed at the lateral faces of the substrate 10 after the split would be less than in the case of splitting the substrate along the target split line L. The regions in which the first modified portions 11 and the second modified portions 12 are positioned side by side in the first direction have low mechanical strength because of the high density of cracks extending from the modified portions. Thus, split positions can easily shift from the first modified portions 11 towards the second modified portions 12. If that were to occur, the substrate 10 would be split at positions that deviate from the target split lines L which could allow some third modified portions 13 to not be exposed at the lateral faces of the substrate 10 after the split.

According to this embodiment, the number of the first modified portions 11 arranged in the thickness direction Z is less than the number of the third modified portions 13 arranged in the thickness direction Z. The number of first modified portions 11 arranged in line with multiple third modified portions 13 in the thickness direction Z may be one. In comparing the numbers of third modified portions 13 and first modified portions 11 in a group of modified portions arranged in the thickness direction Z, the number of the first modified portions 11 is set to be equal to or less than the number of the third modified portions 13. In other words, the number of pairs of first modified portion 11 and second modified portion 12 that are side by side in the first direction is set to be equal to or less than the number of the third modified portions arranged in the thickness direction Z between the first modified portions 11 and the first face 10A. Limiting the number of pairs of first modified portion 11 and second modified portion 12 arranged side by side in the first direction can keep the volume of the portion having a high crack density around the first modified portions 11 from becoming too large, thereby making the shifting of split positions towards the second modified portions 12 less likely. This, as a result, can facilitate the splitting of the substrate 10 along the target split lines L that respectively pass through all of the third modified portions 13 and all of the first modified portions 11 arranged in the thickness direction Z. This can make it difficult for the number of modified portions exposed at the lateral faces of the substrate 10 to be reduced, thereby facilitating the extraction of light from the lateral faces of the substrate 10. As described above, moreover, in the process of splitting the substrate in the present disclosure, the substrate 10 begins to split from the first face 10A side. In the process of splitting the substrate, if a high crack density portion is present near the face at which the splitting of the substrate 10 begins, the splitting positions can easily shift. According to this embodiment, first modified portions 11 and second modified portions 12 that are side by side in the first direction are not provided on the first face 10A side, making it unlikely for a high crack density portion to be present within the substrate 10 on the first face 10A side. This can make the shifting of splitting positions of the substrate 10 less likely, thereby reducing the likelihood of reduction in the number of modified portions exposed at the lateral faces of the substrate 10.

In the case of providing a single first modified portion 11 relative to multiple third modified portions 13 arranged in the thickness direction Z, two or more third modified portions 13 are provided. When multiple third modified portions 13 and multiple first modified portions 11 are arranged in the thickness direction Z, the number of the first modified portions 11 is set to be less than the number of the third modified portions 13.

In comparing the numbers of third modified portions 13 and first modified portions 11 in a group of modified portions arranged in the thickness direction Z, the difference between the number of third modified portions 13 and the number of first modified portions 11 is preferably three or less, more preferably two or less. In other words, the difference between (i) and (ii) is preferably three or less, more preferably two or less, where (i) is the number of pairs of first modified portion 11 and second modified portion 12 that are side by side in the first direction, and (ii) is the number of third modified portions 13 arranged in the thickness direction Z between the first modified portions 11 and the first face 10A. Setting the difference between the number of third modified portions 13 and the number of pairs of first modified portion 11 and second modified portion 12 to three or less can facilitate the formation of cracks from the first modified portions 11 and the second modified portions 12 in the thickness direction Z, thereby facilitating the splitting of even a thick substrate 10.

According to the example shown in FIG. 2, as described above, in the process of forming multiple first modified portions 11 by conducting the first process multiple times, at least a first portion 11A which is positioned closest to the second face 10B, a second portion 11B which is positioned closer to the first face 10A than the first portion 11A is, and a third portion 11C which is positioned closer to the first face 10A than the second portion 11B is, are formed.

The distance d1 between the first portion 11A and the second face 10B in the thickness direction Z is preferably set to be smaller than the distance between the first portion 11A and the first face 10A in the thickness direction Z. In other words, among a group of modified portions arranged in the thickness direction Z including multiple third modified portions 13 and multiple first modified portions 11, the first portion 11A located closest to the second face 10B is formed at a position that is closer to the second face 10B than the first face 10A. This can reduce the likelihood of the cracks originating from the first modified portions 11 and the third modified portions 13 to be concentrated near the first face 10A, thereby facilitating the splitting of the substrate 10.

The distance d2 between the first portion 11A and the second portion 11B in the thickness direction Z is preferably set larger than the distance d3 between the second portion 11B and the third portion 11C in the thickness direction Z. Not allowing the second portion 11B formed at a position that is second closest to the second face 10B to be too close to the first portion 11A while forming the first portion 11A at a position that is closer to the second face 10B than the first face 10A for facilitating the splitting of the substrate 10 can reduce the thermal damage to the semiconductor layers 20 that results from the laser light irradiation applied when forming the second portion 11B.

Furthermore, to reduce the thermal damage to the semiconductor layers 20 attributable to the laser light irradiation applied when forming the first portion 11A, the distance d1 between the first portion 11A and the second face 10B in the thickness direction Z is preferably set larger than the distance d2 between the first portion 11A and the second portion 11B in the thickness direction Z. Setting the distance d1 to be larger than the distance d2 while forming the first portion 11A at a position that is closer to the second face 10B than the first face 10A can facilitate the splitting of the substrate 10 while reducing the thermal damage to the semiconductor layers 20.

The distance between the first modified portion 11 that is closest to the third modified portions 13 (the third portion 11C in this case) and the third modified portions 13 in the thickness direction Z, and the distance in the thickness direction Z between third modified portions 13 that are adjacent in the thickness direction Z can be set to be about the same as the distance d3 described above, for example.

The distance d4 between the first face 10A and at least the third modified portion 13 that is closest to the first face 10A among the multiple third modified portions 13 in the thickness direction Z can be set, for example, to be larger than the distance d3 and smaller than the distance d2.

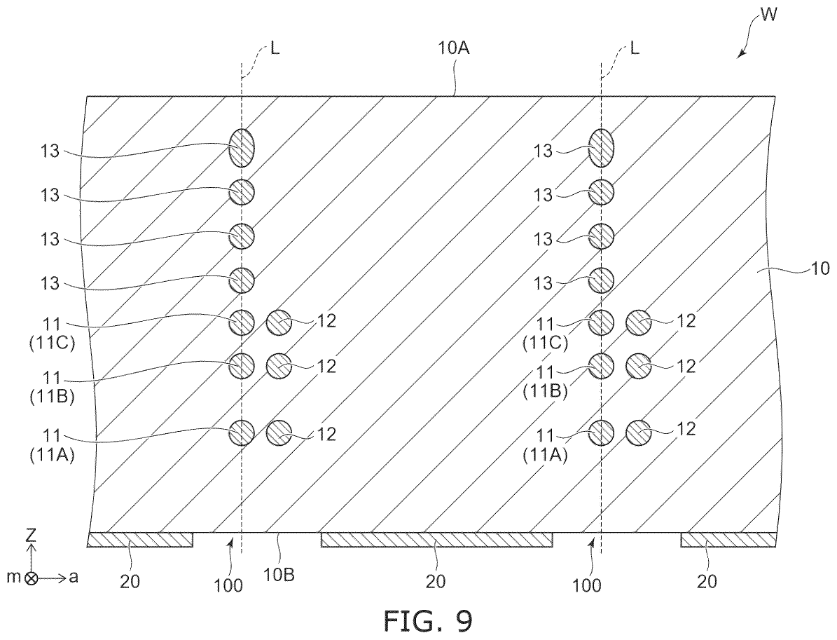

According to a first variation of this embodiment shown in FIG. 9, the length in the thickness direction Z of at least the third modified portion 13 that is closest to the first face 10A among the third modified portions 13 is set to be larger than the length in the thickness direction Z of a first modified portion 11 which is next to a second modified portion 12. The length in the thickness direction Z of the third modified portion 13 closest to the first face 10A can be set, for example, to 1.1 to 1.5 times the length in the thickness direction Z of the first modified portion 11. For example, the length of the first modified portion 11 in the thickness direction Z can be set to 5 μm to 30 μm.

Multiple cracks can originate from a modified portion in multiple directions. Furthermore, a crack can branch out. Lengthening a third modified portion 13 in the thickness direction Z can facilitate the extension of a crack from the third modified portion 13 in the thickness direction Z. Lengthening the third modified portion 13 that is closest to the first face 10A in the thickness direction Z and facilitating the extension of a crack from the third modified portion along the thickness direction Z can reduce the number of cracks that reach the first face 10A. This can make the substrate 10 less prone to chipping during the process of splitting the substrate 10.

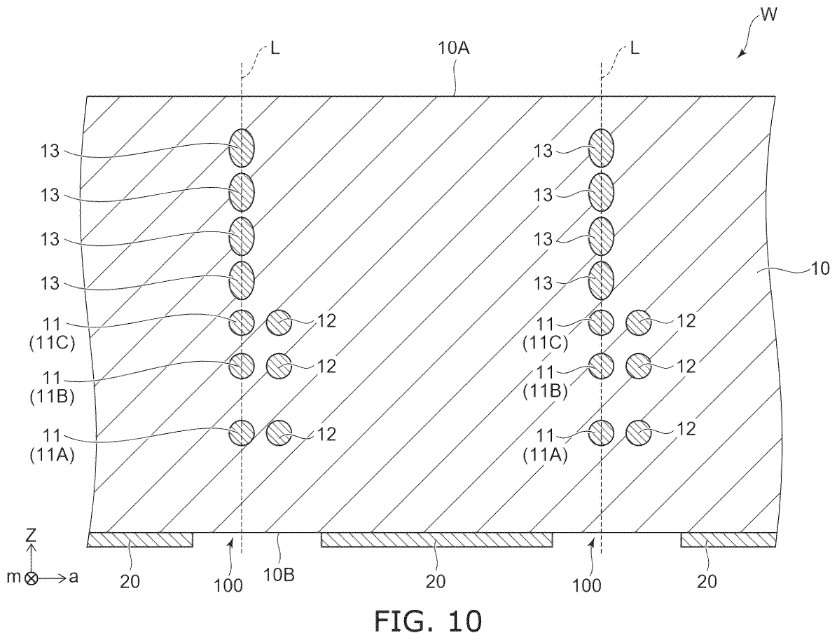

As in the case of a second variation of this embodiment shown in FIG. 10, the lengths of all of the third modified portions 13 in the thickness direction Z may be made larger than the lengths of the first modified portions 11 in the thickness direction. This can further facilitate the reduction of the number of cracks reaching the first face 10A, thereby making the substrate even less prone to chipping.

An example of a method of controlling the length of a modified portion in the thickness direction Z will be explained below.

In irradiating laser light to form modified portions, the refractive index difference between the air and the first face 10A of the substrate 10 can cause spherical aberrations at a laser light focusing position within the substrate. A spherical aberration is a phenomenon in which rays of laser are not converged in one focal point, and resulting in a spread. Such a spherical aberration can be corrected by using a spatial light modulator. For the spatial light modulator, for example, one that includes a liquid crystal layer displaying a predetermined modulation pattern can be used.

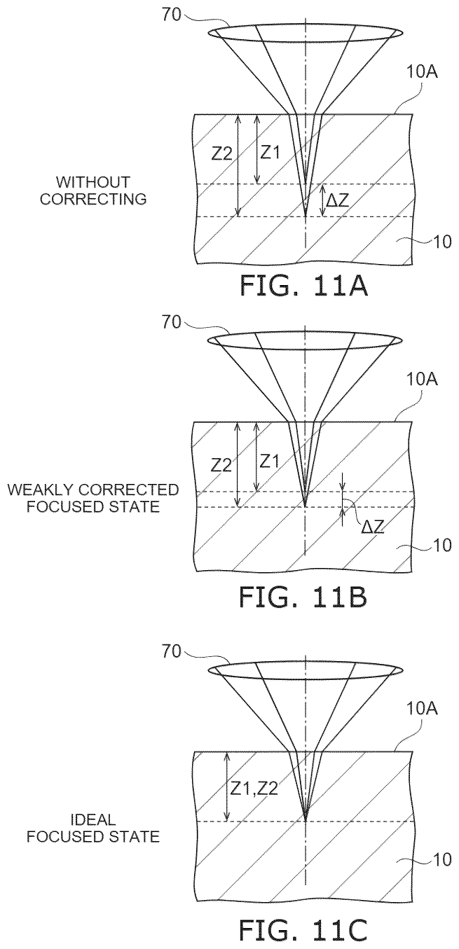

FIG. 11A to FIG. 11C are diagrams explaining how laser light applied from midair to irradiate the substrate 10 via a condensing lens 70 is focused within the substrate 10. FIG. 11A to FIG. 11C are cross sections parallel to the thickness direction of the substrate 10.

FIG. 11A is a diagram explaining a state in which light is focused without correcting aberrations. FIG. 11B is a diagram explaining a weakly corrected focused state using a smaller aberration correction amount than an ideal aberration correction amount. FIG. 11C is a diagram explaining an ideal focused state.

The ideal focused state is a state in which aberrations are corrected so as to cancel the spherical aberrations occurring at a focal point of laser light, i.e., aberrations are reduced to approximate the focused state achieved based on the assumption that there is no medium (sapphire substrate). An ideal aberration correction amount is one that achieves the ideal focused state in a medium. A weakly corrected focused state is a state in which aberrations are corrected so that the spherical aberrations is canceled to bring the state close to the ideal focused state. The aberration correction amount in a weakly corrected state is smaller than the ideal aberration correction amount.

As shown in FIG. 11A, when aberrations are not corrected, for example, the distance Z2 between the first face 10A and the focal point of the outer rays of laser light becomes larger than the distance Z1 between the first face 10A and the focal point of the inner rays of laser light, producing a difference AZ between the distance Z1 and the distance Z2. The distance Z1 and the distance Z2 are distances in the thickness direction of the substrate 10.

As shown in FIG. 11B, in a weakly corrected focused state, for example, the distance Z2 is larger than the distance Z1, but the difference AZ is smaller than in the case of not correcting aberrations.

As shown in FIG. 11C, in the ideal focused state, the distance Z1 is equal to the distance Z2, i.e., there is no difference AZ.

The smaller the aberration correction amount, i.e., the closer the focused state to that shown in FIG. 11A without aberration correction, the larger the length of the focused region of laser light in the thickness direction Z can result, i.e., a modified portion can be lengthened in the thickness direction Z. Accordingly, among the focused states shown in FIG. 11A to FIG. 11C, the state achieved without correcting aberrations shown in FIG. 11A results in the longest laser light focused region in the thickness direction Z, i.e., the largest modified portion in length in the thickness direction Z. In the weakly corrected focused state shown in FIG. 11B, the length of a modified portion in the thickness direction Z can be made smaller than that in the focused state without aberration correction shown in FIG. 11A, and larger than that in the ideal focused state shown in FIG. 11C. Accordingly, setting the laser light aberration correction amount for forming at least the third modified portion 13 that is closest to the first face 10A among multiple third modified portions 13 smaller than the laser light aberration correction amount for forming a first modified portion 11 can make the length in the thickness direction Z of at least the third modified portion 13 that is closest to the first face 10A among multiple third modified portions 13 larger than the length in the thickness direction Z of the first modified portion 11. For example, the ideal focused state can be applied to the first modified portion 11.

As described above, by conducting laser light scanning along the a-axis direction and the m-axis direction of the substrate 10 which is a sapphire substrate, first modified portions 11, second modified portions 12, and third modified portions 13 are formed along the a-axis direction and the m-axis direction. FIG. 2 shows a cross section that includes the first modified portions 11, the second modified portions 12, and the third modified portions 13 formed along the m-axis direction. FIG. 6 shows a cross section that includes the first modified portions 11, the second modified portions 12, and the third modified portions 13 formed along the a-axis direction.

According to this embodiment, the number of first modified portions 11 formed by laser light scanning along the a-axis direction and arranged in the thickness direction Z (two in the example shown in FIG. 6) is set to be less than the number of first modified portions 11 formed by laser light scanning along the m-axis direction and arranged in the thickness direction (three in the example shown in FIG. 2).

A sapphire substrate more readily splits in the a-axis direction than the m-axis direction. This is because cracks extend easily in the direction in which a sapphire substrate tends to fracture during the laser scanning conducted along the a-axis direction.

Accordingly, the number of times the first process is performed in the a-axis laser scanning can be less than the number of times the first process is performed in the m-axis laser scanning. Reducing the number of times the first process is performed can reduce the laser light irradiation induced thermal damage to the semiconductor layers 20. By performing the first process less times in the a-axis laser scanning than the first process performed in the m-axis laser scanning, the number of first modified portions 11 arranged in the thickness direction Z formed by the a-axis laser scanning can be made less than the number of first modified portions 11 arranged in the thickness direction Z formed by the m-axis laser scanning. As in the example shown in FIG. 6, when reducing the number of times the first process is performed in the a-axis laser scanning, the number of times the second process is performed is preferably increased by the same number as the reduction in the first process. This can increase the number of modified portions exposed after splitting the substrate 10, thereby increasing the areas through which light is extracted easily.

### [Semiconductor Element]

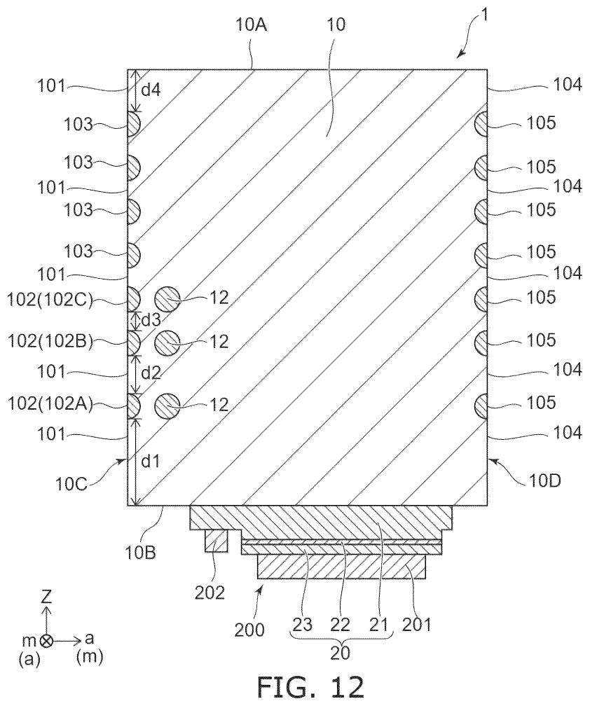

A semiconductor element 1 according to an embodiment will be explained with reference to FIG. 12. The semiconductor element 1 is formed by the method of manufacturing a semiconductor element described above with reference to FIG. 1 to FIG. 8B.

The semiconductor element 1 includes a substrate 10. The substrate 10 is, for example, a sapphire substrate. The substrate 10 has a first face 10A, a second face 10B, a first lateral face 10C connecting the first face 10A and the second face 10B, and a second lateral face 10D positioned opposite the first lateral face 10C in the first direction that is parallel to the first face 10A and connecting the first face 10A and the second face 10B.

The cross section shown in FIG. 12 is the cross section of the substrate 10 split along a target split line L described above. The cross section of the substrate 10 shown in FIG. 12 is orthogonal to the m-axis or the a-axis. Assuming that the cross section of the substrate 10 shown in FIG. 12 is a section orthogonal to the m-axis, the first direction is parallel to the a-axis. Assuming that the cross section of the substrate 10 shown in FIG. 12 is a section orthogonal to the a-axis, the first direction is parallel to the m-axis.

The semiconductor element 1 is, for example, a light emitting element. The semiconductor element 1 includes a light emitting part 200 that includes semiconductor layers 20 disposed on the second face 10B of the substrate 10. The semiconductor layers 20 include an n-side semiconductor layer 21, an active layer 22, and a p-side semiconductor layer 23. The n-side semiconductor layer 21 is disposed on the second face 10B of the substrate 10, for example. The active layer 22 is positioned between the n-side semiconductor layer 21 and the p-side semiconductor layer 23 in the thickness direction Z of the substrate 10. The light emitting part 200 has a p-side electrode 201 electrically connected to the p-side semiconductor layer 23 and an n-side electrode 202 electrically connected to the n-side semiconductor layer 21. The light emitted by the active layer 22 is extracted from the semiconductor element 1 primarily through the first face 10A, the first lateral face 10C, and the second lateral face 10D of the substrate 10.

The first lateral face 10C of the substrate 10 includes a first region 101, multiple second regions 102, and multiple third regions 103 that are positioned closer to the first face 10A than the second region 102 is and arranged in the thickness direction Z of the substrate 10. The second regions 102 are where the first modified portion 11 described above is exposed at the first lateral face 10C as a result of splitting the substrate 10. The third regions 103 are where the third modified portions 13 described above are exposed at the first lateral face 10C as a result of splitting the substrate 10. The first region 101 is the non-modified portion that is exposed at the first lateral face 10C as a result of splitting the substrate 10. In the first lateral face 10C, the second regions 102 and the third regions 103 have a surface roughness larger than that of the first region 101. As described above, light is more easily scattered in the second regions 102 and the third regions 103 than the first region 101. This can reduce the amount of light that is reflected back into the substrate 10, thereby facilitating light extraction.

The second lateral face 10D of the substrate 10 has a fourth region 104 and multiple fifth regions 105 that are arranged in the thickness direction Z of the substrate 10. Each of the fifth regions 105 is where one of the first modified portions 11 and the third modified portions 13 described above is exposed at the second lateral face 10D as a result of splitting the substrate 10. The fourth region 104 is where the non-modified portion is exposed at the second lateral face 10D as a result of splitting the substrate 10. In the second lateral face 10D, the fifth regions 105 have a larger surface roughness than that of the fourth region 104. As described above, light is more easily scattered in the fifth regions 105 than in the fourth region 104. This can reduce the amount of light that is reflected back into the substrate 10, thereby facilitating light extraction.

Assuming that the cross section shown in FIG. 12 is orthogonal to the m-axis, multiple second regions 102 are arranged in the m-axis direction in the first lateral face 10C. Assuming that the cross section shown in FIG. 12 is orthogonal to the a-axis, multiple second regions 102 are arranged in the a-axis direction in the first lateral face 10C. The second regions 102 arranged in the first lateral face 10C along the m-axis direction or the a-axis direction may be connected with or apart from one another in the m-axis direction or the a-axis direction.

Assuming that the cross section shown in FIG. 12 is orthogonal to the m-axis, multiple third regions 103 are arranged in the m-axis direction in the first lateral face 10C. Assuming that the cross section shown in FIG. 12 is orthogonal to the a-axis, multiple third regions 103 are arranged in the a-axis direction in the first lateral face 10C. The third regions 103 arranged in the first lateral face 10C along the m-axis direction or the a-axis direction may be connected with or apart from one another in the m-axis direction or the a-axis direction.

Assuming that the cross section shown in FIG. 12 is orthogonal to the m-axis, multiple fifth regions 105 are arranged in the m-axis direction in the second lateral face 10D. Assuming that the cross section shown in FIG. 12 is orthogonal to the a-axis, multiple fifth regions 105 are arranged in the a-axis direction in the second lateral face 10D. The fifth regions 105 arranged in the second lateral face 10D along the m-axis direction or the a-axis direction may be connected with or apart from one another in the m-axis direction or the a-axis direction.

The substrate 10 includes modified portions 12 within the substrate 10 disposed next to the second regions 102 in the first direction. The modified portions 12 are those that are formed next to the first modified portions 11 in the first direction described above. In this embodiment, the distance between the first lateral face 10C and the modified portions 12 in the first direction is smaller than the distance between the second lateral face 10D and the modified portions 12 in the first direction.

The second regions 102 and the modified portions 12 correspond to the first modified portions 11 and the second modified portions 12 that are side by side in the region where the semiconductor layers 20 described above are not provided. Accordingly, “next to the second regions 102 in the first direction” means being next within the width of the region in which semiconductor layers 20 are absent. A cross section of the substrate 10 of a semiconductor element 1 singulated after splitting the substrate 10, does not include second modified portions 12 that were positioned next to the first modified portions 11 which become the fifth regions 105 within the width of the region having no semiconductor layers 20, i.e., no modified portions 12 exist next to the fifth regions 105. Furthermore, no modified portions are provided between the third regions 103 and the fifth regions 105 in the first direction within the substrate 10. Within the substrate 10, modified portions (second modified portions 12) are provided only next to the second regions 102.

In the first lateral face 10C, the number of second regions 102 arranged in the thickness direction Z is one or more, but is equal to or less than the number of third regions 103 arranged in the thickness direction Z. In the case in which multiple third regions 103 and multiple second regions 102 are lined up in the thickness direction Z, the number of the second regions 102 in the thickness direction Z is less than the number of the third regions 103 in the thickness direction Z. When multiple second regions 102 are arranged in the thickness direction Z, a modified portion 12 is provided next to each of the second regions 102 in the first direction.

When multiple second regions 102 are arranged in the thickness direction Z, the second regions 102 include at least a first part region 102A that is closest to the second face 10B, a second part region 102B positioned closer to the first face 10A than the first part region 102A is, and a third part region 102C positioned closer to the first face 10A than the second part region 102B is. The first part region 102A is where the first portion 11A among the first modified portions 11 described above is exposed at the first lateral face 10C. The second part region 102B is where the second portion 11B among the first modified portions 11 described above is exposed at the first lateral face 10C. The third part region 102C is where the third portion 11C among the first modified portions 11 described above is exposed at the first lateral face 10C.

In this embodiment, the distance d1 between the first part region 102A and the second face 10B in the thickness direction Z is smaller than the distance between the first part region 102A and the first face 10A in the thickness direction Z. In this embodiment, the distance d2 between the first part region 102A and the second part region 102B in the thickness direction Z is larger than the distance d3 between the second part region 102B and the third part region 102C in the thickness direction Z. In this embodiment the distance d1 between the first part region 102A and the second face 10B in the thickness direction Z is larger than the distance d2 between the first part region 102A and the second part region 102B in the thickness direction Z. In this embodiment, the distance d4 between the first face 10A and the third region 103 that is closest to the first face 10A among the third regions 103 arranged in the thickness direction Z is smaller than the distance d1 and larger than the distance d3.

In a semiconductor element made by the method of manufacturing a semiconductor element according to the first variation explained with reference to FIG. 9, the length in the thickness direction Z of the third region 103 that is closest to the first face 10A among the third regions 103 arranged in the thickness direction Z is larger than the length in the thickness direction Z of a second region 102.

In a semiconductor element made by the method of manufacturing a semiconductor element according to the second variation explained with reference to FIG. 10, the thickness direction lengths of all of the third regions 103 arranged in the thickness direction Z are larger than the length of a second region 102 in the thickness direction Z.

The number of second regions 102 formed along the a-axis direction and arranged in the thickness direction Z may be set to be less than the number of third regions formed along the m-axis direction and arranged in the thickness direction Z.

Embodiments of the present disclosure can include the methods of manufacturing semiconductor elements and the semiconductor elements described below.

In the foregoing, certain embodiments of the present invention have been explained with reference to specific examples. The present invention, however, is not limited to these specific examples. All forms implementable by a person having ordinary skill in the art by suitably making design changes based on any of the embodiments of the present invention described above also fall within the scope of the present invention so long as they encompass the subject matter of the present invention. Furthermore, various modifications and alterations within the spirit of the present invention that could have been made by a person having ordinary skill in the art also fall within the scope of the present invention.

What is claimed is:

1. A method of manufacturing a semiconductor element, the method comprising:
providing a substrate having a first face and a second face;
a first process comprising:
forming a first modified portion by irradiating laser light within the substrate from a first face side of the substrate, and
subsequent to the forming of the first modified portion, forming a second modified portion at a position next to the first modified portion in a first direction that is parallel to the first face by irradiating laser light from the first face side at a position apart from the first modified portion in the first direction;
subsequent to the first process, forming a plurality of third modified portions arranged in a thickness direction of the substrate at positions that overlap the first modified portion in a plan view and are closer to the first face than is the first modified portion by irradiating laser light from the first face side; and
subsequent to the forming of the third modified portions, splitting the substrate by pressuring the substrate from a second face side using a pressure member, wherein:
no modified portion is formed next to the third modified portions in the first direction to overlap the second modified portions in the plan view, and
a number of the first modified portions arranged in the thickness direction is equal to or less than a number of the third modified portions arranged in the thickness direction.

2. The method of manufacturing a semiconductor element according to claim 1, wherein:
the first process is conducted multiple times so as to arrange a plurality of the first modified portions in the thickness direction of the substrate, the first modified portions overlapping one another in the plan view, and
the number of the first modified portions arranged in the thickness direction of the substrate is less than the number of the third modified portions arranged in the thickness direction of the substrate.

3. The method of manufacturing a semiconductor element according to claim 1, wherein:
semiconductor layers are disposed on the second face of the substrate,
the forming of the first modified portion comprises forming at least a first portion that is closest to the second face, a second portion that is positioned closer to the first face than is the first portion is, and a third portion that is closer to the first face than is the second portion,
a distance between the first portion and the second face in the thickness direction is smaller than a distance between the first portion and the first face in the thickness direction, and
a distance between the first portion and the second portion in the thickness direction is larger than a distance between the second portion and the third portion in the thickness direction.

4. The method of manufacturing a semiconductor element according to claim 3, wherein the distance between the first portion and the second face in the thickness direction is larger than the distance between the first portion and the second portion in the thickness direction.

5. The method of manufacturing a semiconductor element according to claim 1, wherein a thickness direction length of at least a third modified portion closest to the first face among the plurality of third modified portions is larger than a thickness direction length of the first modified portion.

6. The method of manufacturing a semiconductor element according to claim 5 wherein thickness direction lengths of all of the third modified portions are larger than the thickness direction length of the first modified portion.

7. The method of manufacturing a semiconductor element according to claim 1, wherein:
the substrate is a sapphire substrate,
scanning of laser light is conducted along an a-axis direction and a m-axis direction of the sapphire substrate to thereby form the first modified portions, the second modified portions, and the third modified portions along the a-axis direction and the m-axis direction, and
a number of the first modified portions formed by the scanning of the laser light in the a-axis direction and arranged in the thickness direction is less than a number of the first modified portions formed by the scanning of the laser light in the m-axis direction and arranged in the thickness direction.

8. A semiconductor element comprising:
a substrate having a first face, a second face, a first lateral face connecting the first face and the second face, and a second lateral face positioned opposite the first lateral face in a first direction that is parallel to the first face and connecting the first face and the second face; and
a semiconductor layer disposed on the second face, wherein:
the first lateral face comprises:
a first region,
a second region having a surface roughness larger than a surface roughness of the first region, and
a plurality of third regions positioned closer to the first face than is the second region, having a surface roughness larger than the surface roughness of the first region, and arranged in a thickness direction of the substrate,
the second lateral face comprises:
a fourth region, and
a plurality of fifth regions having a surface roughness larger than a surface roughness of the fourth region and arranged in the thickness direction,
the substrate comprises a modified portion within the substrate, the modified portion being positioned only next to the second region in the first direction,
a distance between the first lateral face and the modified portion in the first direction is smaller than a distance between the second lateral face and the modified portion in the first direction, and
a number of the second regions arranged in the thickness direction is less than a number of the third regions arranged in the thickness direction.

9. The semiconductor element according to claim 8, wherein:
the semiconductor element comprises a plurality of the second regions and a plurality of the modified portions,
the second regions are arranged in a plurality of positions in the thickness direction,
the modified portions are respectively positioned next to the second regions in the first direction, and
the number of the second regions arranged in the thickness direction is less than the number of the third regions arranged in the thickness direction.

10. The semiconductor element according to claim 8, wherein:
the second regions comprise at least a first part region that is closest to the second face, a second part region that is positioned closer to the first face than is the first part region, and a third part region that is positioned closer to the first face than is the second part region,
a distance between the first part region and the second face in the thickness direction is smaller than a distance between the first part region and the first face in the thickness direction, and
a distance between the first part region and the second part region in the thickness direction is larger than a distance between the second part region and the third part region in the thickness direction.

11. The semiconductor element according to claim 10, wherein the distance between the first part region and the second face in the thickness direction is larger than the distance between the first part region and the second part region in the thickness direction.

12. The semiconductor element according to claim 8, wherein a thickness direction length of at least a third region that is closest to the first face among the third regions is larger than a thickness direction length of the second region.

13. The semiconductor element according to claim 12, wherein thickness direction lengths of all of the third regions are larger than the thickness direction length of the second region.

14. The semiconductor element according to claim 8, wherein:
the substrate is a sapphire substrate,
the second regions and the third regions are formed along the a-axis direction and the m-axis direction of the sapphire substrate, and
a number of the second regions formed along the a-axis direction and arranged in the thickness direction is less than a number of the third regions formed along the m-axis direction and arranged in the thickness direction.
